(19) United States
(12) Patent Application Publication
(10) Pub. No.: US 2020/0119134 A1
(43) Pub. Date: Apr. 16, 2020

(54) EMBEDDED STACK CAPACITOR WITH HIGH PERFORMANCE LOGIC

(71) Applicant: International Business Machines Corporation, Armonk, NY (US)

(72) Inventor: Effendi Leobandung, Stormville, NY (US)

(21) Appl. No.: 16/157,718

(22) Filed: Oct. 11, 2018

(51) Int. Cl. H01L 49/02; H01L 23/522; H01L 27/105; H01L 25/18

(52) U.S. Cl. CPC H01L 28/60; H01L 25/18; H01L 27/105; H01L 23/5223

(57) ABSTRACT

A semiconductor structure with embedded stacked capacitors and a method for fabricating the same are provided. In an embodiment, a method for fabricating logic and memory devices with an embedded stack capacitor includes forming a semiconductor chip having a logic region and a memory region. The method also includes forming back-end-of-line (BEOL) metallization over the logic region but not over the memory region. The method also includes forming a stack capacitor over the memory region.

### BACKGROUND

The disclosure relates generally to semiconductor structures and, more specifically, to stacked capacitors and methods for fabricating stacked capacitors.

Semiconductor fabrication involves manufacturing integrated circuits in semiconductor substrates. The process involves forming transistors and other devices directly in semiconductor substrates, such as silicon. Capacitors are one type of component formed in semiconductor substrates. Types of capacitors formed in semiconductor substrates include deep trench capacitors and stack capacitors. A stack capacitor is more advantageous as compared to deep trench capacitors since stack capacitors are cheaper and do not consume as much silicon real estate as deep trench capacitors do, thereby allowing this saved silicon real estate to be dedicated to more transistors. Stack capacitors can be used for embedded memory or in memory computing for artificial intelligence applications.

However, stack capacitors usually block a thick layer of metallization that makes it difficult to integrate advanced logic devices. Therefore, the stack capacitor that is more easily integrated with advanced logic devices is desirable.

### SUMMARY

According to one embodiment of the present invention, a method for fabricating logic and memory devices with an embedded stack capacitor is provided. The method includes forming a semiconductor chip having a logic region and a memory region. The method also includes forming back-end-of-line (BEOL) metallization over the logic region but not over the memory region. The method also includes forming a stack capacitor over the memory region.

According to another embodiment of the present invention, a semiconductor device includes a semiconductor substrate comprising a first region and a second region. The semiconductor device also includes a plurality of logic devices formed in the first region and a plurality of memory devices formed in the second region. The semiconductor device also includes a stack capacitor formed over the second region.

According to another embodiment of the present invention, a method for fabricating a semiconductor device having an embedded stack capacitor integrated with logic devices and memory devices includes forming a logic region on a semiconductor chip. The method also includes forming a memory region on the semiconductor chip. The method also includes forming metallization layers for the logic region. The method also includes forming a stack capacitor over the memory region.

### BRIEF DESCRIPTION OF THE DRAWINGS

FIG. 1 is a cross sectional view of a prior art semiconductor device;

FIGS. 2-10 are cross-sectional views of a semiconductor device with embedded stacked capacitors at various stages of fabrication in accordance with an illustrative embodiment; and

FIG. 11 is a flowchart of a process for fabricating a semiconductor with logic devices, memory devices, and stacked capacitors integrated with the logic devices and the memory devices, as depicted in accordance with an illustrative embodiment.

### DETAILED DESCRIPTION

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive.

Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

For purposes of the description hereinafter, the terms “upper,” “lower,” “right,” “left,” “vertical,” “horizontal,” “top,” “bottom,” and derivatives thereof shall relate to the embodiments of the disclosure, as it is oriented in the drawing figures. The terms “positioned on” means that a first element, such as a first structure, is present on a second element, such as a second structure, wherein intervening elements, such as an interface structure, e.g. interface layer, may be present between the first element and the second element.

In this disclosure, when an element, such as a layer, region, or substrate is referred to as being “on” or “over” another element, the element can be directly on the other element or intervening elements can also be present. In contrast, when an element is referred to as being “directly on,” “directly over,” or “on and in direct contact with” another element, there are no intervening elements present, and the element is in contact with another element.

The processes, steps, and structures described below do not form a complete process flow for manufacturing integrated circuits. The disclosure can be practiced in conjunction with integrated circuit fabrication techniques currently used in the art, and only so much of the commonly practiced process steps are included as necessary for an understanding of the different examples of the present disclosure. The figures represent cross sections of a portion of an integrated circuit during fabrication and are not drawn to scale, but instead are drawn so as to illustrate different illustrative features of the disclosure.

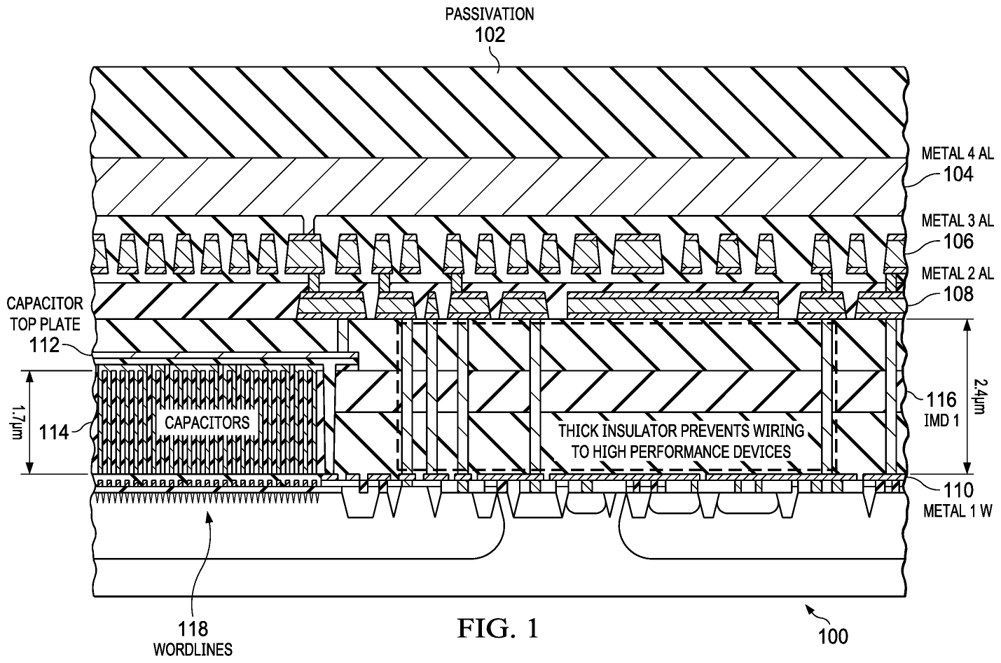

With reference now to the figures and, in particular, with reference to FIG. 1, a cross sectional view of a prior art semiconductor device 100 is depicted. Semiconductor device 100 is an example of a device with capacitors embedded in the device 100. The device 100 includes passivation layer 102 over a plurality of metallization layers 104, 106, 108, 110. The device also includes a plurality of capacitors 114 formed over a plurality of wordlines 118 between metallization layer 110 and a capacitor top plate 112. The device also includes an inter-metal dielectric (IMD) layer 116. The upper metallization layers 104, 106, 108 may be copper (Cu) and the lower metallization layer 110 may be tungsten (W). The distance between the first and second metallization layers 110, 108 is about 2.4 microns. The distance between the first metallization layer 110 and the capacitor top plate 112 is 1.7 microns. The IMD layer 116 is thick due to the presence of the capacitors 114. The thick insulator of the IMD layer 116 prevents wiring to high performance devices.

The disclosed methods, systems, and devices described below overcome this technical problem with existing semiconductor devices with embedded capacitors. In an embodiment, a method of forming a semiconductor device with embedded stacked capacitors is provided. In an embodiment, a semiconductor device with an embedded stacked capacitor is provided that does not include a thick insulator thereby allowing for wiring to high performance devices. These and other advantages are provided by one or more of the disclosed embodiments.

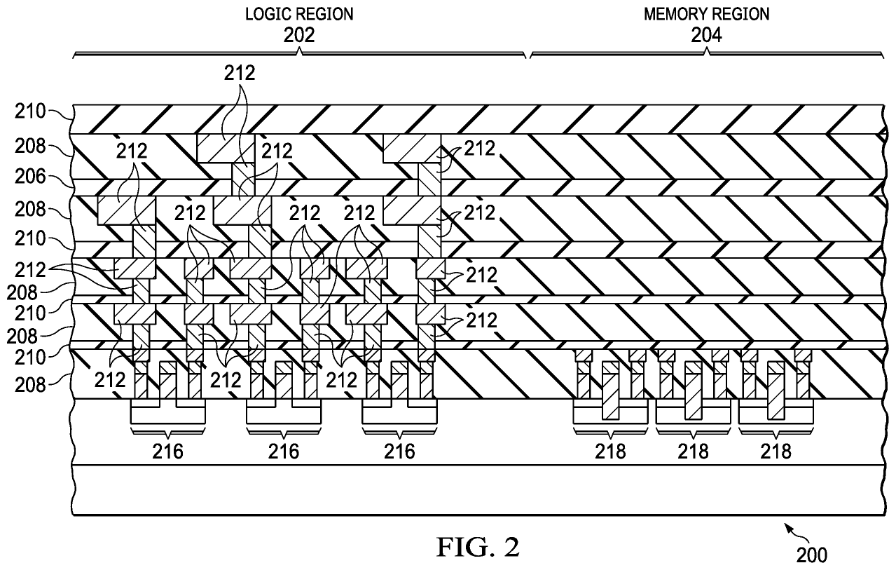

FIGS. 2-10 are cross-sectional views of a semiconductor device 200 with embedded stacked capacitors at various stages of fabrication in accordance with an illustrative embodiment. The series of drawings illustrate an embodiment process for fabricating a semiconductor device 200 with embedded stacked capacitors.

FIG. 2 is a cross-sectional view of a semiconductor device 200 before processing to form stacked capacitors in accordance with an illustrative embodiment. The device 200 includes a logic region 202 and a memory region 204. The logic region 202 of the device 200 includes a plurality of logic devices 216 and a plurality of metallization layers or vias 212 (i.e., back-end-of-line (BEOL) wiring), connecting various terminals of the logic devices 216 to other components (not shown) within the device 200. The memory region 204 includes a plurality of memory devices 218. Thus, at this stage of fabrication, the device 200 includes wiring for BEOL metal in the form of the vias 212 over the logic devices 216 in the logic region 202, but not over the memory devices 218 in the memory region 204. The device 200 also includes alternating layers of first layers 208 and second layers 210. In an embodiment, the first layer 208 is a low-k material or oxide. In an embodiment, the second layer 210 is a barrier low-k (BLOK) or NBLOK or Silicon Nitride. A third layer 206 separates the top first layer 208 and the top second layer 210 from the remaining first and second layers 208, 210.

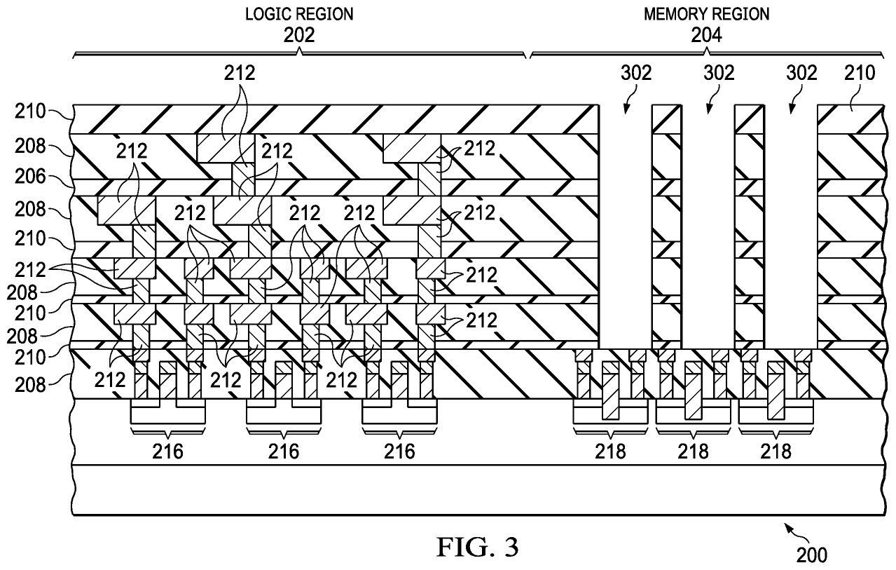

After the device 200 shown in FIG. 2 is fabricated, the device 200 is patterned to produce holes 302 for the stack capacitor as shown in FIG. 3.

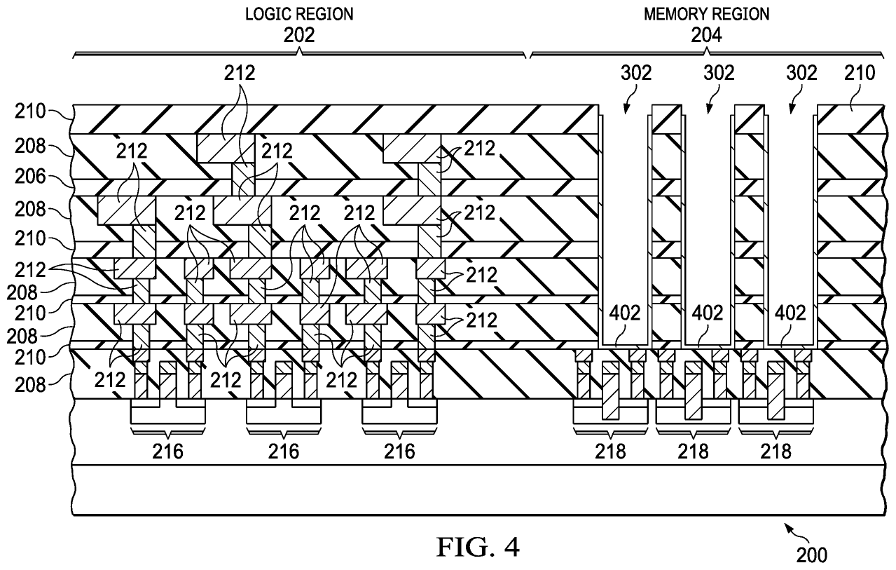

After the stack capacitor holes 302 have been formed in the device 200, the capacitor bottom electrode 402 is deposited in each of the holes 302 as depicted in FIG. 4. In an embodiment, the capacitor bottom electrode 402 is hemispherical grained (HSG) doped silicon. In other embodiments, the capacitor bottom electrode 402 is a metal, such as, for example, copper (Cu), tungsten (W), or gold (Au). In yet other embodiments, the capacitor bottom electrode 402 may be any electrically conductive material.

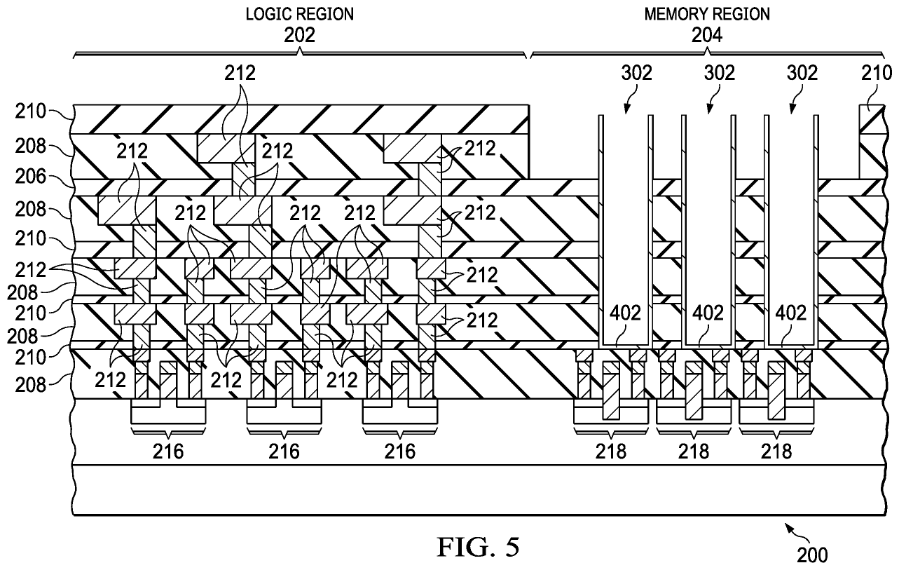

Next, the top layer of the first material 208 and the top layer of the second material 210 are etched away in the memory region 204 only as illustrated in FIG. 5.

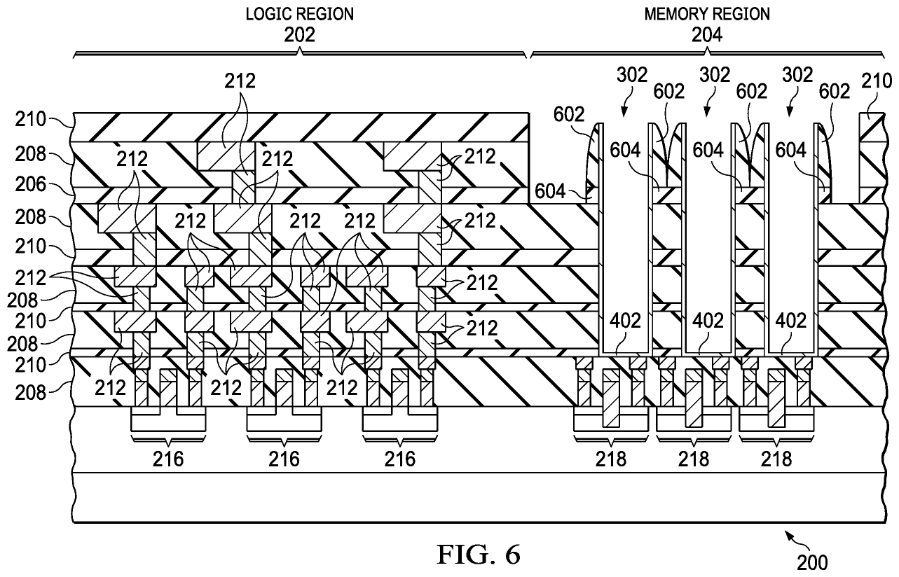

Next, a low-k or oxide spacer 602 is formed on the sides of the capacitor bottom electrode 402, and the portions 604 of the third layer 206 of nitride in the memory region 204, that are not covered by the spacer 602, are etched away or otherwise removed, as shown in FIG. 6.

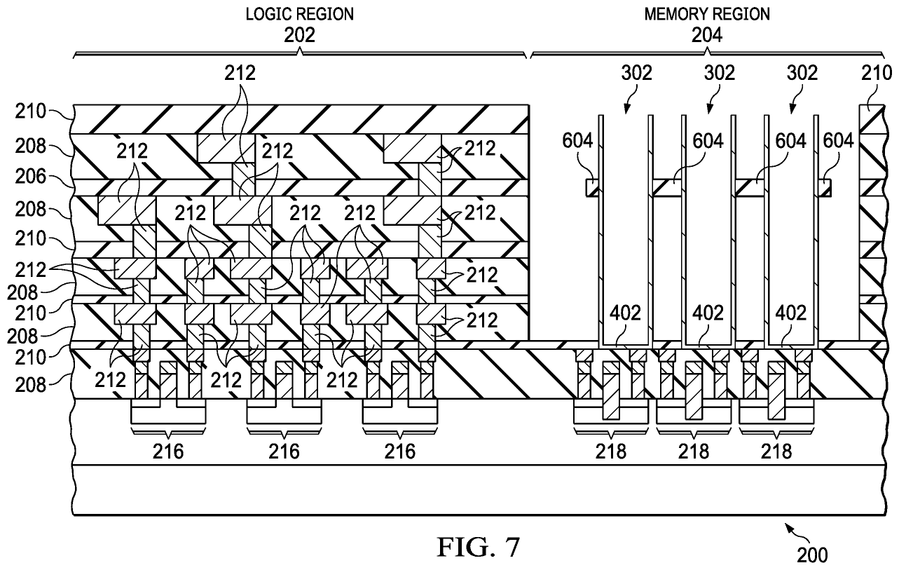

Next, all of the oxide and low-k material, including first and second layers 208, 210 and spacers 602, is removed from the memory region 204 as shown in FIG. 7. In an embodiment, the oxide and low-k material is removed with a combination of anisotropic and isotropic etches. The barrier material 210 can also be removed selective to support layer 604. However, it is also possible to leave that layer as is.

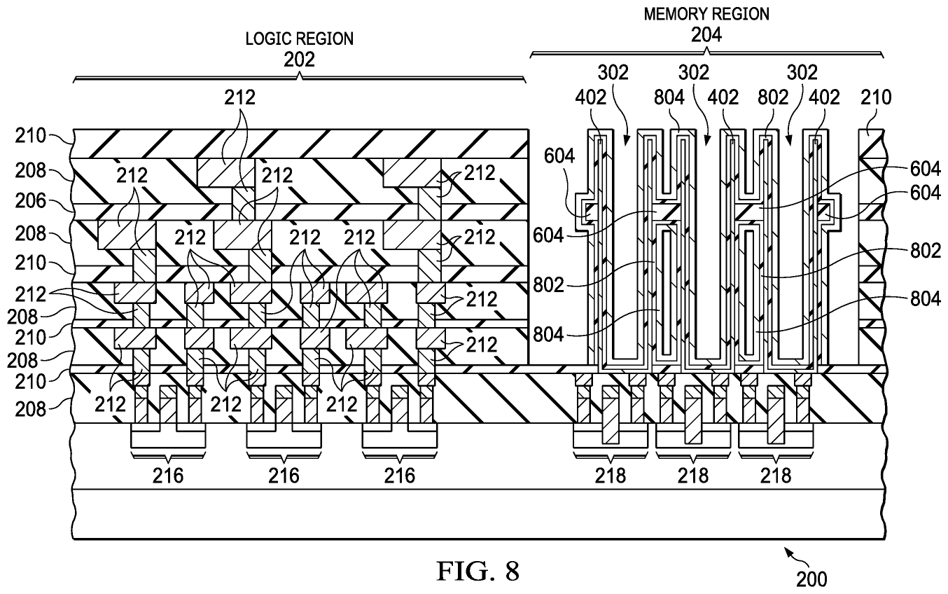

Next, a capacitor dielectric 802 and a capacitor top electrode 804 are deposited over the memory region and removed from the unwanted regions such that the capacitor dielectric 802 and capacitor top electrode 804 only cover the areas around the capacitor bottom electrodes and regions between the capacitor bottom electrodes as shown in FIG. 8. In an embodiment, the capacitor dielectric is a high-k material such as, for example, hafnium dioxide (HfO₂), aluminum oxide (Al₂O₃), and zirconium dioxide (ZrO₂). In an embodiment, the capacitor top electrode 804 is hemispherical grained (HSG) doped silicon. In other embodiments, the capacitor top electrode 804 is a metal, such as, for example, copper (Cu), tungsten (W), or gold (Au). In yet other embodiments, the capacitor top electrode 804 may be any electrically conductive material. In an embodiment, the capacitor top electrode 804 is fabricated from the same material as the capacitor bottom electrode 402. In other embodiments, the capacitor top electrode 804 is fabricated from a different material from that of the capacitor bottom electrode 402.

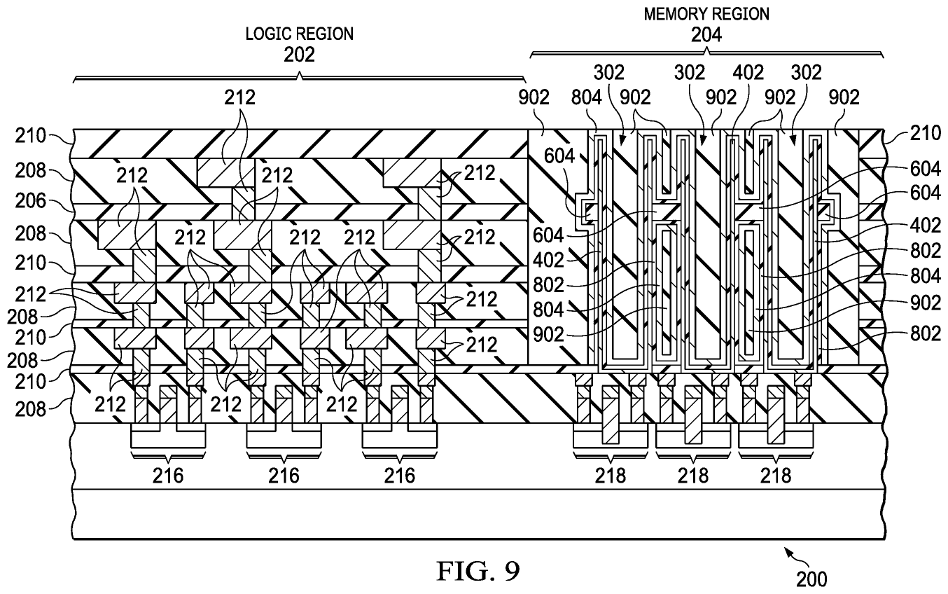

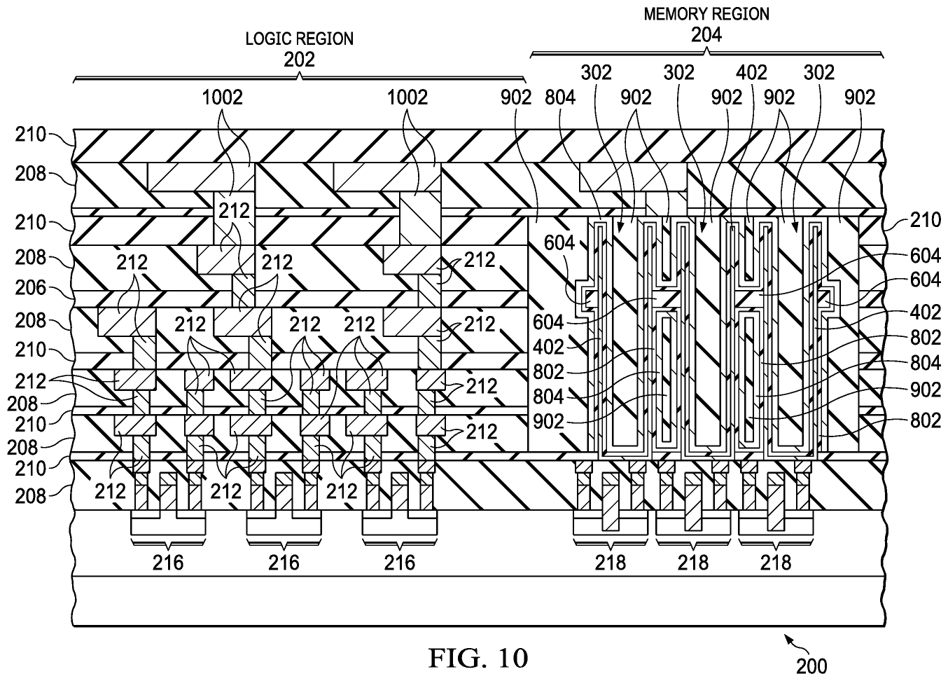

Next, the device 200 is planarized with a dielectric low-k or oxide material 902 as shown in FIG. 9. After the device 200 is planarized, the fabrication process continues with further BEOL processing adding additional metal layers 1002 as shown in FIG. 10. The number of metal layers is implementation dependent and, in one embodiment, may include between 1 and 10 additional metal layers.

Thus, in an illustrative embodiment, an embedded stack capacitor structure is provided that does not include a thick metallization layer that inhibits performance and reduces the number of components that can be fabricated on a device. In an illustrative embodiment, an embedded stack capacitor that includes high performance logic devices and low leakage memory devices is provided.

As a result, the processes illustrated in FIGS. 2-10 overcome a technical problem with integrating stacked capacitors with advanced logic devices. One or more technical solutions are present in the illustrative example that allows the fabrication of integrated stack capacitors with advanced logic that also allows high performance wiring to be integrated into the semiconductor device.

The illustration of process for fabricating the embedded stacked capacitor structures in FIGS. 2-10 is not meant to imply physical or architectural limitations to the manner in which an illustrative embodiment may be implemented. Other components in addition to or in place of the ones illustrated may be used. Some components may be unnecessary. Also, the blocks are presented to illustrate some functional components. One or more of these blocks may be combined, divided, or combined and divided into different blocks when implemented in an illustrative embodiment.

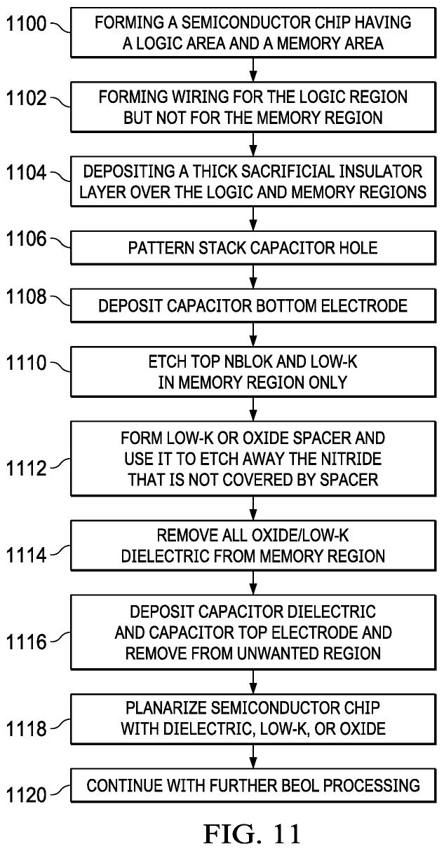

Turning next to FIG. 11, a flowchart of a process for fabricating a semiconductor with logic devices, memory devices, and stacked capacitors integrated with the logic devices and the memory devices is depicted in accordance with an illustrative embodiment. The process illustrated in FIG. 11 can be implemented to perform the steps described for fabricating an embedded stack capacitor 200 depicted in FIGS. 2-10.

The process begins by forming a semiconductor chip having a logic region and a memory region (step 1100). Next, the process forms wiring for the logic region, but not for the memory region (step 1102). Next, a thick sacrificial insulator layer is deposited over the logic and memory regions (step 1104). The process then patterns the stack capacitor hole or holes if multiple stack capacitors are being formed (step 1106). Next, the process deposits the capacitor bottom electrode (step 1108) and then the top NBLOK and low-k is etched over the memory region only (step 1110). Next, the process forms a low-k or oxide spacer which is used to etch away the nitride that is not covered by the spacer (step 1112). Next, all oxide/low-k dielectric are removed from the memory region (step 1114). The process then deposits the capacitor dielectric and the capacitor top electrode and removes the capacitor dielectric and the top electrode from unwanted regions leaving the capacitor dielectric and the top electrode in the stacked capacitor only (step 1116). Next, the process planarizes the semiconductor chip with dielectric, low-k material, or oxide (step 1118). The process then continues with further BEOL processing (step 1120) producing BEOL metallization layers, after which, the process may terminate.

The flowcharts and block diagrams in the different depicted embodiments illustrate the architecture, functionality, and operation of some possible implementations of apparatuses and methods in an illustrative embodiment. In this regard, each block in the flowcharts or block diagrams may represent at least one of a module, a segment, a function, or a portion of an operation or step. For example, one or more of the blocks may be implemented as program code, hardware, or a combination of the program code and hardware. When implemented in hardware, the hardware may, for example, take the form of integrated circuits that are manufactured or configured to perform one or more operations in the flowcharts or block diagrams. When implemented as a combination of program code and hardware, the implementation may take the form of firmware. Each block in the flowcharts or the block diagrams may be implemented using special purpose hardware systems that perform the different operations or combinations of special purpose hardware and program code run by the special purpose hardware.

In some alternative implementations of an illustrative embodiment, the function or functions noted in the blocks may occur out of the order noted in the figure. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

For example, additional steps showing detailed steps for forming the logic and memory devices as well as the metallization layers for the logic region may be present although not described in the flowcharts.

Thus, illustrative embodiments of the present invention provide a computer implemented method, computer system, and computer program product for fabricating a semiconductor chip with embedded stacked capacitors. The process begins by forming a semiconductor chip having a logic region and a memory region. The process then continues by forming back-end-of-line (BEOL) metallization for the logic region but not for the memory region. Next, the process then continues by forming a stacked capacitor over the memory region.

The process utilized to create the structure, results in a semiconductor with embedded stacked capacitors with better utilization of space to allow for a denser concentration of logic and memory components.

The methods and structures that have been described above with reference to figures in the different examples may be employed in any electrical device including integrated circuit chips. The integrated circuit chips including the disclosed structures and formed using the disclosed methods may be integrated with other chips, discrete circuit elements, and/or other signal processing devices as part of either an intermediate product, such as a motherboard, or an end product. The end product can be any product that includes integrated circuit chips, including computer products or devices having a display, a keyboard or other input device, and a processor unit.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiment. The terminology used herein was chosen to best explain the principles of the embodiment, the practical application or technical improvement over technologies found in the marketplace, or to enable others of ordinary skill in the art to understand the embodiments disclosed here.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

What is claimed is:

1. A method for fabricating a semiconductor device having an embedded stack capacitor integrated with logic devices and memory devices, the method comprising:
forming a semiconductor chip having a logic region and a memory region;
forming back-end-of-line (BEOL) metallization layers over the logic region but not over the memory region; and
forming a stack capacitor over the memory region.

2. The method of claim 1, further comprising:
forming further BEOL metallization layers.

3. The method of claim 1, wherein forming the stack capacitor further comprises:
patterning a stack capacitor hole over at least a portion of the memory region.

4. The method of claim 3, wherein forming the stack capacitor further comprises:
depositing a capacitor bottom electrode.

5. The method of claim 4, wherein forming the stack capacitor further comprises:
etching away a top NBLOK and low-k material from above the memory region without removing the top NBLOK and low-k material from above the logic region.

6. The method of claim 5, wherein forming the stack capacitor further comprises:
forming a spacer, the spacer comprising one of a low-k material and an oxide;
etching away nitride that is not covered by the spacer; and
removing the spacer.

7. The method of claim 6, wherein forming the stack capacitor further comprises:
depositing a capacitor dielectric over the memory region; and
removing the capacitor dielectric from an unwanted region of the semiconductor device.

8. The method of claim 7, wherein forming the stack capacitor further comprises:
depositing a capacitor top electrode over the capacitor dielectric.

9. A semiconductor device comprising:
a semiconductor substrate comprising a first region and a second region;
a plurality of logic devices formed in the first region;
a plurality of memory devices formed in the second region; and
a stack capacitor formed over the second region.

10. A method for fabricating a semiconductor device having an embedded stack capacitor integrated with logic devices and memory devices, the method comprising:
forming a logic region on a semiconductor chip;
forming a memory region on the semiconductor chip;
forming metallization layers for the logic region; and
forming a stack capacitor over the memory region.

11. The method of claim 10, wherein the metallization layers comprise back-end-of-line (BEOL) metallization layers.

12. The method of claim 10, wherein forming the stack capacitor further comprises:
patterning a stack capacitor hole over at least a portion of the memory region.

13. The method of claim 12, wherein forming the stack capacitor further comprises:
depositing a capacitor bottom electrode.

14. The method of claim 13, wherein forming the stack capacitor further comprises:
etching away a top NBLOK and low-k material from above the memory region without removing the top NBLOK and low-k material from above the logic region.

15. The method of claim 14, wherein forming the stack capacitor further comprises:
forming a spacer, the spacer comprising one of a low-k material and an oxide; and
etching away nitride that is not covered by the spacer.

16. The method of claim 15, wherein forming the stack capacitor further comprises:
depositing a capacitor dielectric over the memory region; and
removing the capacitor dielectric from an unwanted region of the semiconductor device.

17. The method of claim 16, wherein forming the stack capacitor further comprises:
depositing a capacitor top electrode over the capacitor dielectric.

18. The method of claim 10, further comprising:
forming further metallization layers.
